(19) United States
(12) Patent Application Publication
(10) Pub. No.: US 2026/0164710 A1
(43) Pub. Date: Jun. 11, 2026

(54) SEMICONDUCTOR DEVICE

(71) Applicant: Vanguard International Semiconductor Corporation, Hsinchu (TW)

(72) Inventors: Tzu-Hsuan CHEN, Hsinchu City (TW); Yu-Jui CHANG, Hsinchu City (TW); Chien-Hsien SONG, Kaohsiung City (TW); Yun-Kai LAI, Taichung City (TW); Chia-Hao LEE, Zhubei City (TW); Chung-Ren LAO, Taichung City (TW); Chih-Cherng LIAO, Zhudong Township (TW); Chen-Dong TZOU, Taipei City (TW)

(73) Assignee: Vanguard International Semiconductor Corporation, Hsinchu (TW)

(21) Appl. No.: 18/972,469

(22) Filed: Dec. 6, 2024

(51) Int. Cl. H10D 30/66; H10D 30/01; H10D 30/60; H10D 62/10

(52) U.S. Cl. CPC H10D 30/668; H10D 30/611; H10D 62/124; H10D 30/0297

(57) ABSTRACT

A semiconductor device includes: a substrate having a first conductivity type; an epitaxial layer on the substrate and having the first conductivity type; a trench structure and a well region having a second conductivity type both extending in the second direction that extend from the top surface of the epitaxial layer into the epitaxial layer, and separating from each other by a distance in the first direction, wherein the trench structure includes a conductive portion and an insulating layer covering the sidewalls and the bottom surface of the conductive portion; a first heavily doped portion having the first conductivity type and a second heavily doped portion having the second conductivity type that are formed in the well region and alternately disposed in the second direction; and a gate structure extending in the second direction on the top surface of the epitaxial layer and over the well region.

### BACKGROUND OF THE INVENTION

### Field of the Invention

The present invention relates to semiconductor devices, and in particular it relates to miniaturized semiconductor devices.

### Description of the Related Art

The semiconductor industry continues to improve the integration density of different electronic components by continuously reducing minimum element sizes so that more components can be integrated into a given area. For example, metal-oxide-semiconductor field effect transistors (MOSFET), which are widely used in power switch elements, utilize a vertical structure to reduce cell pitch and increase functional density. It utilizes the backside of the chip as the drain electrode and forms the sources and gates of multiple transistors on the front side of the chip, so that the drive current develops from a planar flow to a vertical flow, which allows the semiconductor device to achieve a high reverse withstand voltage and a low on-state resistance.

However, as the functional density requirements for semiconductor devices continue to increase, the complexity of the components integrated into semiconductor devices and the methods of their formation also increases. As a result, while existing semiconductor devices are generally appropriate and adequate for their intended purposes, they are not entirely satisfactory in all respects.

### BRIEF SUMMARY OF THE INVENTION

An embodiment of the present invention provides a semiconductor device. The semiconductor device includes a substrate having a first conductivity type. The semiconductor device includes an epitaxial layer formed on the substrate and having the first conductivity type. The semiconductor device includes a trench structure extending from a top surface of the epitaxial layer into the epitaxial layer, and including a conductive portion and an insulating layer that covers a sidewall and a bottom surface of the conductive portion. The semiconductor device includes a well region extending from the top surface of the epitaxial layer into the epitaxial layer and having a second conductivity type. The well region is separated from the trench structure in a first direction, and the well region extends in a second direction. The second direction is different from the first direction. The semiconductor device includes at least one first heavily doped portion and at least one second heavily doped portion formed in the well region and extending in the first direction. The first heavily doped portion and the second heavily doped portion are alternately disposed in the second direction. The first heavily doped portion has the first conductivity type and the second heavily doped portion has the second conductivity type. The semiconductor device includes a gate structure formed on the top surface of the epitaxial layer and corresponding to the well region. The gate structure extends in the second direction.

### BRIEF DESCRIPTION OF THE DRAWINGS

The present invention can be more fully understood by reading the subsequent detailed description and examples with references made to the accompanying drawings, wherein:

FIGS. 1A, 1B, 1C, 1E-1 and 1E-2 show the schematic cross-sectional views of a semiconductor device at an intermediate manufacturing stage, according to some embodiments of the present disclosure.

FIG. 2 shows the top view of a semiconductor device at an intermediate manufacturing stage, according to some embodiments of the present disclosure.

FIG. 3 shows the top view of a semiconductor device at an intermediate manufacturing stage, according to some embodiments of the present disclosure.

FIGS. 4A and 4B show the schematic cross-sectional view and the top view, respectively, of a semiconductor device at an intermediate manufacturing stage, according to some embodiments of the present disclosure.

FIGS. 5A and 5B show the schematic cross-sectional view and the top view, respectively, of a semiconductor device at an intermediate manufacturing stage, according to some embodiments of the present disclosure.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some variations of the embodiments are described below. Similar reference numerals are used to designate similar elements in the different drawings and illustrated embodiments. It should be noted that additional steps can be provided before, during and after the method provided in the method, and some of the steps described can be replaced, or eliminated for other embodiments of the method.

The present disclosure provides semiconductor devices and methods of forming the same, and in some embodiments, the semiconductor suitable for scaled-down or miniaturized semiconductor devices may be formed. The embodiments may be applied to metal-oxide-semiconductor (MOS) devices, such as metal-oxide semiconductor field-effect transistors (MOSFETs). In some of the following embodiments, a MOSFET comprising a planar gate and a conductive trench structure is used as an example of a semiconductor device.

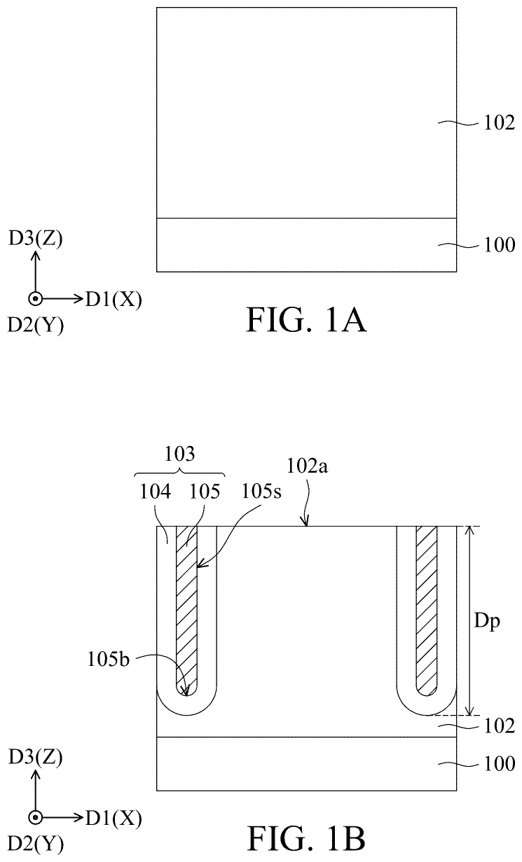

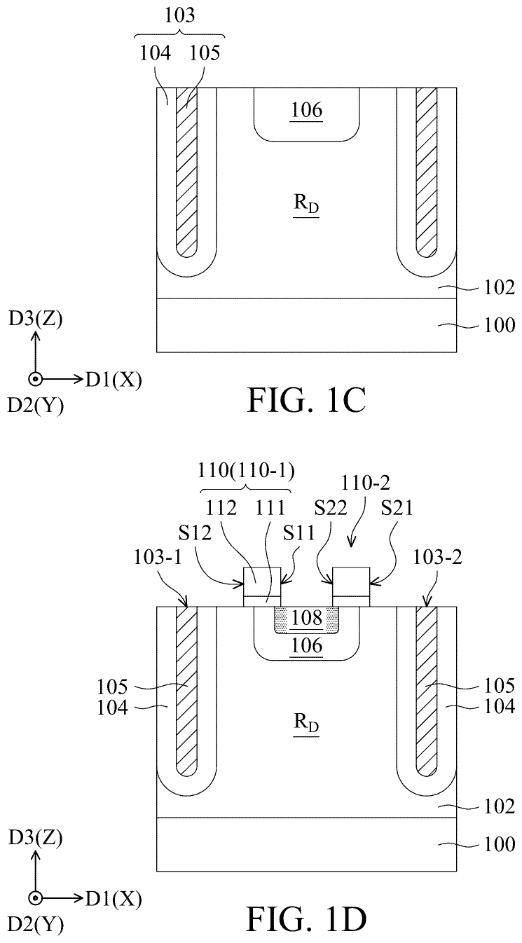

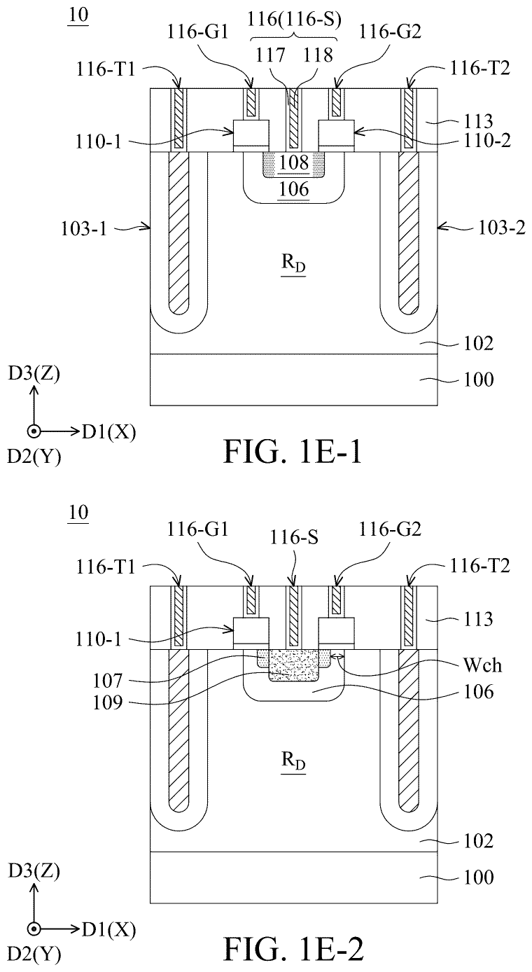

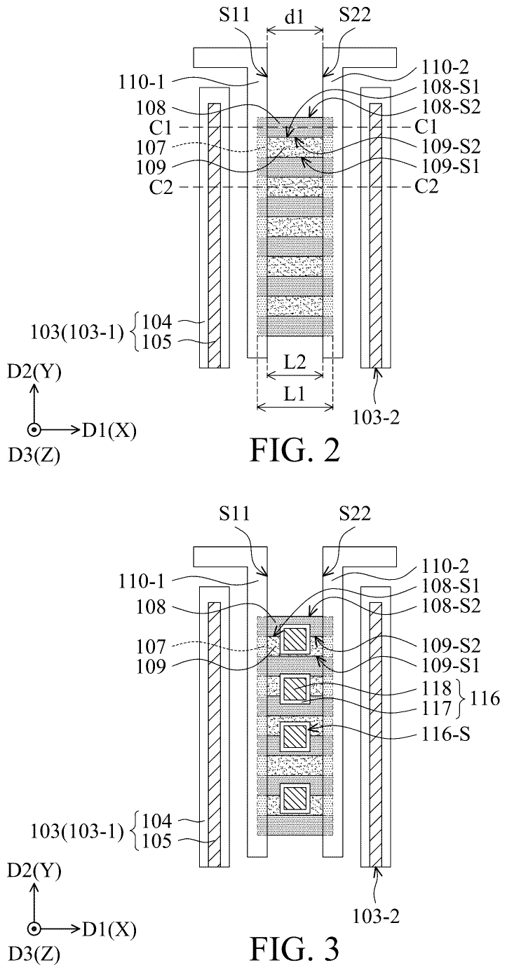

FIGS. 1A, 1B, 1C, 1E-1 and 1E-2 show the schematic cross-sectional views of a semiconductor device at an intermediate manufacturing stage, according to some embodiments of the present disclosure.

Referring to FIG. 1A, according to some embodiments, a substrate 100 having a first conductivity type is provided. In some embodiments, the substrate 100 may be a bulk semiconductor substrate, such as a semiconductor wafer. For example, the substrate 100 is a silicon wafer. In some embodiments, the substrate 100 may be made of silicon or other semiconductor materials, or the substrate 100 may include other elemental semiconductor materials, such as germanium. In some embodiments, the substrate 100 may include a compound semiconductor, such as silicon carbide, gallium nitride. In some embodiments, the substrate 100 may include an alloy semiconductor such as silicon germanium, silicon germanium carbide, or other suitable materials. In some embodiments, the substrate 100 may be composed of multiple layers of materials, such as silicon/silicon germanium, silicon/silicon carbide.

In this example, the substrate 100 is, for example, a silicon wafer doped with a dopant of the first conductivity type. In the application of a vertical conductive trench MOSFET, the substrate 100 of the first conductivity type may function as a drain region of the semiconductor device. Furthermore, in this example, the first conductivity type is n-type, but the present disclosure is not limited thereto. In some other examples, the first conductivity type may be p-type.

In some embodiments, an epitaxial growth process is conducted to form an epitaxial layer 102 on the substrate 100. The substrate 100 and the epitaxial layer 102 have the same conductivity type. In this example, epitaxial layer 102 has the first conductivity type, such as n-type. In some embodiments, the doping concentration of the epitaxial layer 102 is less than the doping concentration of the substrate 100. In the application of a vertical trench-gate MOSFET, the epitaxial layer 102 with the first conductivity type may function as a drift region of the semiconductor device.

In some embodiments, the epitaxy growth process above may be conducted by metal organic chemical vapor deposition (MOCVD), plasma-enhanced chemical vapor deposition (plasma-enhanced CVD; PECVD), molecular beam epitaxy (MBE), hydride vapor epitaxy (HVPE), liquid phase epitaxy (LPE), chloride vapor phase epitaxy (Cl-VPE), other suitable process methods, or a combination thereof.

Next, referring to FIG. 1B, according to some embodiments, a plurality of trench structures 103 are formed in the epitaxial layer 102. According to some embodiments of the present disclosure, the position of the trench structures 103 may be defined through a suitable photolithographic patterning process. Afterwards, a portion of the epitaxial layer 102 may be removed through an etching process to form recesses in the epitaxial layer 102 (not shown). In some embodiments, the positions of these recesses correspond to the position of the trench structures 103 shown in FIG. 1B. The depth of these recesses in the epitaxial layer 102, for example, along the third direction D3, is equal to the depth Dp of the subsequently formed trench structures 103 in the epitaxial layer 102. The etching process mentioned above includes a dry etching process, a wet etching process, a plasma etching process, a reactive ion etching process, other suitable processes, or a combination thereof. In addition, it can be understood that the size, the shape and the position of the recesses and the trench structures 103 formed therein are only for illustrative purposes and are not intended to limit the embodiments of the present disclosure.

Each trench structure 103 includes an insulating layer 104 and a conductive portion 105, wherein the insulating layer 104 covers the sidewall 105s and the bottom surface 105b of the conductive portion 105. In some embodiments, as shown in FIG. 1B, the trench structures 103 are separated from each other in the first direction D1, and each trench structure 103 extends along the second direction D2 in the epitaxial layer 102. In this example, two trench structures 103 are shown in the figure for clarity.

According to the mutual configuration of the trench structure 103 proposed in the embodiment and other features formed subsequently, the electrical performance of the formed semiconductor device can be improved. For example, if the trench structure 103 is electrically connected to the gate subsequently, the on-state resistance can be greatly reduced. On the other hand, if the trench structure 103 is electrically connected to the source subsequently, the on-state resistance can be effectively reduced while also having good dynamic characteristics, such as shortening the switching time of turning on and off, and greatly reducing switching energy loss.

The trench structure 103 proposed in the embodiment may be electrically coupled to the source or the gate, so the insulating layer 104 and the conductive portion 105 can be appropriately selected according to the coupling situation in actual applications.

In some embodiments in which the trench structure 103 is electrically coupled to the source, the insulating layer 104 may be silicon oxide, germanium oxide, other suitable semiconductor oxide materials, or a combination thereof. In some examples, an insulating material may be isotropically formed on the sidewalls and bottom surfaces of the recesses and on the top surface 102a of the epitaxial layer 102 through an oxidation process. In some embodiments, the oxidation process may be a thermal oxidation, a radical oxidation, or other suitable processes. In some embodiments, a thermal process may be selectively conducted on the insulating material to increase the density of the insulating material. In some embodiments, the aforementioned thermal process may be a rapid thermal annealing (RTA) process.

In some embodiments in which the trench structure 103 is electrically coupled to the gate, that is, the trench structure 103 functions as a trench gate structure, the insulating layer 104 may be silicon oxide, hafnium oxide, zirconium oxide, aluminum oxide, aluminum dioxide-hafnium alloy, silicon hafnium dioxide, silicon hafnium oxynitride, tantalum hafnium oxide, titanium hafnium oxide, zirconium hafnium oxide, other suitable high dielectric constant (high-k) dielectric materials, or a combination thereof. In some embodiments, an insulating material may be formed on the sidewalls and bottom surfaces of the recesses and on the top surface 102a of the epitaxial layer 102 through a deposition process. Such deposition process may be an isotropic deposition process, and may be a physical vapor deposition (PVD) process, a chemical vapor deposition (CVD) process, an atomic layer deposition (ALD) process, other suitable deposition processes, or a combination thereof.

Then, according to some embodiments, a conductive material (not shown) may be deposited on the insulating material through a deposition process, and the conductive material fills the space other than the insulating material in the recesses. Then a thermal process, such as an annealing process, may be selectively conducted on the conductive material. In some embodiments, the conductive material may be a single-layer or multi-layer structure and formed of amorphous silicon, polycrystalline silicon, or a combination thereof. In some examples, the deposition process mentioned before may be a physical vapor deposition (PVD) process, a chemical vapor deposition (CVD) process, other suitable processes, or a combination thereof.

Next, part of the insulating material and part of the conductive material are removed to form the trench structures 103 shown in FIG. 1B. For example, excess portion of the conductive material and excess portion of the insulating material disposed on the top surface 102a of the epitaxial layer 102 may be removed through a planarization process, and expose the top surface 102a of the epitaxial layer 102. The planarization process mentioned above may be, for example, a chemical mechanical polishing (CMP) process, a mechanical polishing process, an etching process, other suitable processes, or a combination thereof.

After the above removal step, the remnant of the insulating material becomes the insulating layer 104, and the remnant of the conductive material becomes the conductive part 105. The conductive part 105 is separated from the epitaxial layer 102 by the insulating layer 104. In some examples, after the planarization process, the conductive portion 105 is disposed on the insulating layer 104, and the top surface of the conductive portion 105 and the top surface of the insulating layer 104 are substantially coplanar with the top surface 102a of the epitaxial layer 102.

In some embodiments, the conductive portion 105 may selectively include the dopant of the first conductivity type, such as an n-type dopant. In some embodiments, the dopant of the conductive portion 105 may be phosphorus or other suitable dopants. In some embodiments in which the trench structure 103 is subsequently electrically connected to the gate, in addition to reducing the on-state resistance by the conductive portion 105 of the trench structure 103, the conductive portion 105 having the first conductivity type can further enhance the effect of the reduced surface filed (RESURF).

After forming the trench structure 103, referring to FIG. 1C, according to some embodiments, a well region 106 is formed in the epitaxial layer 102, and the well region 106 has a conductivity type different from that of the epitaxial layer 102, such as a second conductivity type. In this example, the well region 106 is p-type, and can also be referred as a p-body region. In some embodiments, the well region 106 is spaced apart from the trench structure 103 in the first direction D1, and the well region 106 extends in the second direction D2. In some embodiments, the doping concentration of well region 106 ranges from about 1E16 atoms/cm³ to about 1E18 atoms/cm³. According to some embodiments, the surface of the well region 106 may serve as a channel region of a semiconductor device.

Furthermore, in some embodiments in which the semiconductor device is a vertical-diffused MOS (VDMOS) device, the epitaxial portion other than and below the well region 106 is a drift region R_{D} of the semiconductor device. Accordingly, the drift region R_{D} has the first conductivity type (e.g., n-type) and is in contact with the sidewall and bottom surface of the well region 106 as shown in FIG. 1C.

According to some embodiments, doping from the top surface 102a of the epitaxial layer 102 may be conducted by a deposition process, a lithography patterning process, an etching process, and an implantation process to form a well region 106 in the epitaxial layer 102 as shown in FIG. 1C. Therefore, the well region 106 is doped from the top surface 102a of the epitaxial layer 102 downward to a specific depth of the epitaxial layer 102. Furthermore, the depth of the well region 106 in the epitaxial layer 102 (e.g., along the third direction D3) is smaller than the depth of the trench structure 103 in the epitaxial layer 102 (e.g., along the third direction D3). That is, the bottom surface of the trench structure 103 (i.e., the bottom surface of the insulating layer 104) is closer to the substrate 100 than the bottom surface of the well region 106.

In one example, an oxide hard mask material layer (not shown) may be deposited over the top surface 102a of the epitaxial layer 102, and then a patterned photoresist corresponding to the location of the well region 106 may be formed on this oxide hard mask material layer. The oxide hard mask material layer is etched according to the patterned photoresist to form an oxide hard mask, and the patterned photoresist is removed. Then doping of the epitaxial layer 102 is conducted according to the formed oxide hard mask to form the well region 106 in the epitaxial layer 102, and thereafter the oxide hard mask is removed.

It should be noted that although the cross-sectional view of FIG. 1C could not be shown, each well region 106 is a doping region extending in the first direction D1, the second direction D2 and the third direction D3. Furthermore, in the process of some embodiments, when viewed from above the epitaxial layer 102, the mask defining the well region 106 and the mask defining the trench structure 103 (for example, extending in the first direction D1 and the second direction D2, both not shown) do not overlap in the first direction D1, such that the subsequently formed well region 106 can be spaced an appropriate distance from the trench structure 103 in the first direction D1.

After that, according to some embodiments, the first heavily doped portion 108 and the second heavily doped portion 109 of different conductivity types are formed in the well region 106, and the first heavily doped portion 108 and the second heavily doped portion 109 are alternately disposed along the second direction D2. Moreover, a planar gate is formed on the epitaxial layer 102.

Referring to FIG. 1D and FIG. 2 at the same time, FIG. 2 shows the top view of a semiconductor device at an intermediate manufacturing stage, according to some embodiments of the present disclosure. FIG. 1D is, for example, a schematic cross-sectional view of a semiconductor device taken along the section line C1-C1 of FIG. 2.

As shown in FIGS. 1D and 2, according to some embodiments of the present disclosure, a plurality of first heavily doped portions 108 and a plurality of second heavily doped portions 109 are formed in the well region 106. The first heavily doped portions 108 and the second heavily doped portions 109 are alternately disposed along the second direction D2 (FIG. 2). In some embodiments in which the semiconductor device is a vertical-diffused MOS (VDMOS) device, a channel width Wch of the semiconductor device extends, for example, in the second direction D2. Accordingly, in some embodiments, the first heavily doped portions 108 and the second heavily doped portions 109 in the well region are alternately disposed in the direction of the channel width.

According to some embodiments, the first heavily doped portion 108 has the first conductivity type, such as n-type. The second heavily doped portion 109 has the second conductivity type, such as p-type. In some embodiments in which the semiconductor device is a VDMOS device, the first heavily doped portions 108 may function as source region and the second heavily doped portions 109 may function as bulk region. Further, according to some embodiments, the first heavily doped portions 108 may or may not surround the second heavily doped portions 109.

It should be noted that since FIG. 1D is a cross-section view taken along the section line C1-C1 passing through the first heavily doped portion 108 of FIG. 2, only the first heavily doped portion 108 is shown in the well region 106 in FIG. 1D.

According to some embodiments, a dopant having a first conductive type is doped from the top surface of the well region 106 (i.e., the top surface 102a of the epitaxial layer 102) to form the first heavily doped portions 108. As shown in FIG. 2, the first heavily doped portion 108 extends in a first direction D1 that is different from the extending direction of the gate structure 110 that is subsequently formed (e.g., a second direction D2). In an example, the extending direction of the first heavily doped portion 108 is substantially perpendicular to the extending direction of the gate structure 110. Further, the doping concentration of the first heavily doped portion 108 is greater than the doping concentration of the epitaxial layer 102. In some embodiments, the doping concentration of these first heavily doped portion 108 is, for example, but not limited to, in a range from about 1E18 atoms/cm³ to about 1E21 atoms/cm³.

According to some embodiments, a dopant having a first conductive type may be doped from the top surface 102a of the epitaxial layer 102 to form the first heavily doped portion 108 in the well region 106 by means of a deposition process, a lithography patterning process, an etching process, and an implantation process. In an example, an oxide hard mask material layer (not shown) may be deposited over the top surface 102a of the epitaxial layer 102, and then a patterned photoresist corresponding to the location of the first heavily doped portion 108 may be formed on this oxide hard mask material layer. The oxide hard mask material layer is etched according to the patterned photoresist to form an oxide hard mask, and the patterned photoresist is removed. Then doping of the epitaxial layer 102 is conducted according to the formed oxide hard mask to form the t first heavily doped portion 108 in the epitaxial layer 102, and thereafter the oxide hard mask is removed.

Furthermore, in some embodiments, a dopant having a second conductivity type is doped from the top surface of the well region 106 (i.e., the top surface 102a of the epitaxial layer 102) to form the second heavily doped portion 109. As shown in FIG. 2, the second heavily doped portion 109 extends in the first direction D1, which is different from the extending direction of the subsequently formed gate structure 110 (e.g., the second direction D2). In one example, the extending direction of the second heavily doped portion 109 is substantially perpendicular to the extending direction of the gate structure 110. The doping concentration of the second heavily doped portion 109 is greater than the doping concentration of the well region 106. Furthermore, in some embodiments, the doping concentration of the second heavily doped portions 109 is, for example, but not limited to, in the range of about 1E18 atoms/cm³ to about 1E21 atoms/cm³.

In addition, a dopant having the second conductive type may be doped from the top surface 102a of the epitaxial layer 102 to form the second heavily doped portion 109 in the well region 106 by means of a deposition process, a lithography patterning process, an etching process, and an implantation process. The formation method of the second heavily doped portion 109 may refer to the formation method of the first heavily doped portion 108 mentioned above, and will not be repeated here.

Furthermore, according to some embodiments of the present disclosure, the second heavily doped portion 109 and the first heavily doped portion 108 are alternately disposed in the extending direction of the gate structure 110 (for example, the second direction D2). In an embodiment having at least two first heavily doped portions 108 and two second heavily doped portions 109, if viewed from above the epitaxial layer 102, the first heavily doped portion 108 in the middle is disposed between the two second heavily doped portions 109. Furthermore, in this example, as shown in FIG. 2, when viewed from above the epitaxial layer 102, each second heavily doped portion 109 is disposed between two first heavily doped portions 108.

More specifically, according to some embodiments, the first heavily doped portion 108 connects the second heavily doped portion 109 in the second direction D2. As shown in FIG. 2, the first heavily doped portion 108 includes, for example, opposing first sidewall 108-S1 and second sidewall 108-S2. The second heavily doped portion 109 includes, for example, opposing first sidewall 109-S1 and second sidewall 109-S2. Wherein, the first sidewall 108-S1 of the first heavily doped portion 108 abuts the second side wall 109-S2 of the second heavily doped portion 109, and the second sidewall 109-S2 is adjacent to and at least partially in contact with the first sidewall 108-S1.

Further, according to some embodiments, as shown in FIG. 2, the first heavily doped portion 108 has a first length L1 in the first direction D1, and the second heavily doped portion 109 has a second length L2 in the first direction D1, wherein the first length L1 is greater than the second length L2.

Furthermore, in some embodiments, as shown in FIG. 2, the semiconductor device further includes a lightly doped portion 107 extending in the second direction D2, wherein the lightly doped portion 107 has the same conductivity type as the first heavily doped portion 108, and the edge of the lightly doped portion 107 is substantially aligned with the edge of the first heavily doped portion 108. The lightly doped portion 107 has the first conductivity type, such as n-type. In some examples, before forming the first heavily doped portion 108 and the second heavily doped portion 109, a low concentration dopant having a first conductivity type is doped from the top surface 102a of the epitaxial layer 102 to form the lightly doped portion 107 in the well region 106. The depth of the lightly doped portion 107 in the well region 106 is shallower than that of the first heavily doped portion 108 and the second heavily doped portion 109 formed subsequently. In some embodiments, the doping concentration of the lightly doped portion 107 is, for example, but not limited to, in the range of about 1E14 atoms/cm³ to about 1E16 atoms/cm³.

Furthermore, according to some embodiments of the present disclosure, the extending direction of the lightly doped portion 107, such as the second direction D2, is different from the extending direction of the first heavily doped portion 108 and the second heavily doped portion 109, such as the first direction. In some examples, as shown in FIG. 2, sidewalls of the first heavily doped portion 108 (e.g., first sidewall 108-S1 and second wall 108-S2) and sidewalls of the second heavily doped portion 109 (e.g., first sidewall 109-S1 and second wall 109-S2) are perpendicular to the extending direction of the lightly doped portion 107 (e.g., the second direction D2).

Furthermore, according to some embodiments of the present disclosure, the lightly doped portion 107 extending in the second direction D2 connects the lateral edges of the alternately disposed first heavily doped portion 108 and the second heavily doped portion 109. In an embodiment having at least two first heavily doped portions 108 and one second heavily doped portion 109, if viewed from above the epitaxial layer 102, the second heavily doped portion 109 is surrounded by two adjacent first heavily doped portions 108 and the lightly doped portion 107.

Still referring to FIGS. 1D and 2, according to some embodiments, after the formation of the lightly doped portion 107, the first heavily doped portion 108 and the second heavily doped portion 109, a planar gate structure 110 is formed on the top surface 102a of the epitaxial layer 102. The gate structure 110 corresponds to the well region 106 below and extends along the second direction D2 (FIG. 2). More specifically, the gate structure 110 is disposed across the position corresponding to the well region 106, a portion of the first heavily doped portion 108 in the well region 106, and a portion of the drift region R_{D}.

According to some embodiments, as shown in FIG. 2, the extending direction of the first heavily doped portion 108 and the second heavily doped portion 109 (for example, the first direction D1) is different with the extending direction of the gate structure 110 (for example, the second direction D2).

In some embodiments, as shown in FIG. 1D, the gate structure 110 includes a gate dielectric layer 111 and a gate electrode 112 disposed above the gate dielectric layer 111. Gate dielectric layer 111 may be silicon oxide or other suitable dielectric materials. Gate electrode 112 may include polysilicon or other suitable conductive materials. A dielectric material layer (not shown) may be formed on the epitaxial layer 102 through a deposition process (such as a physical vapor deposition (PVD) process, a chemical vapor deposition (CVD) process, an atomic layer deposition (ALD) process), or a thermal oxidation process. Then, a conductive material (not shown) is deposited on the dielectric material layer. The deposition process may be a physical vapor deposition (PVD) process, a chemical vapor deposition (CVD) process, or other suitable processes. Next, the dielectric material layer and the conductive material may be patterned through a lithography process and an etching process to form the gate dielectric layer 111 and the gate electrode 112 of the gate structure 110.

In this example, a semiconductor device with a symmetric configuration of features is used as an example for explanation. As shown in FIGS. 1D and 2, the two gate structures, corresponding to the well region 106, includes a first gate structure 110-1 corresponding to one side of the well region 106 and a second gate structure 110-2 corresponding to the other side of the well region 106. The first gate structure 110-1 and the second gate structure 110-2 have similar configurations and both extend along the second direction D2. The second gate structure 110-2 is separated from the first gate structure 110-1 in the first direction D1 by a distance, such as the distance d1 shown in FIG. 2.

Furthermore, in this example, as shown in FIGS. 1D and 2, the well region 106 is disposed between two trench structures, such as between the first trench structure 103-1 and the second trench structures 103-2. The first trench structure 103-1 and the second trench structure 103-2 are separated from each other in the first direction D1, and the first gate structure 110-1 and the second gate structure 110-2 are disposed between the first trench structure 103-1 and the second trench structure 103-2. The first trench structure 103-1 and the second trench structure 103-2 have similar configurations. For example, each trench structure includes the insulating layer 104 and the conductive portion 105, wherein the insulating layer 104 covers the sidewall 105s of the conductive portion 105. As shown in FIG. 2, the first trench structure 103-1 and the second trench structure 103-2 both extend in the second direction D2.

Furthermore, according to some embodiments, two opposite end portions of each first heavily doped portion 108 extend to below two adjacent sidewalls of the first gate structure 110-1 and the second gate structure 110-2 and partially overlap the first gate structure 110-1 and the second gate structure 110-2, respectively.

More specifically, in this example, the first gate structure 110-1 has opposing sidewalls S11 and S12, and the second gate structure 110-2 has opposing sidewalls S21 and S22. Two opposite end portions of each first heavily doped portion 108 extend to below the sidewall S11 and the sidewall S22, respectively, and partially overlap the first gate structure 110-1 and the second gate structure 110-2, respectively. In other words, in some embodiments, the projected areas of the two opposite end portions of the first heavily doped portion 108 on the substrate 100 partially overlap the projected areas of the first gate structure 110-1 and the second gate structure 110-2 on the substrate 100, respectively.

According to some embodiments, as shown in FIG. 2, the first heavily doped portion 108 has the first length L1 in the first direction D1, and the second gate structure 110-2 is separated from the first gate structure 110-1 by the distance d1 in the first direction D1. In this example, the first length L1 is greater than the distance d1 between the second gate structure 110-2 and the first gate structure 110-1.

Further, according to some embodiments, two opposite end portions of each second heavily doped portion 109 extend to below two adjacent sidewalls of the first gate structure 110-1 and the second gate structure 110-2, respectively. The second heavily doped portions 109 may or may not partially overlap the first gate structure 110-1 and the second gate structure 110-2.

More specifically, in this example, the two opposite end portions of each second heavily doped portion 109 extend to below the sidewall S11 of the first gate structure 110-1 and the sidewall S22 of the second gate structure 110-2, respectively. For example, the two opposite end portions of the second heavily doped portion 109 extend to below the sidewall S11 and the side wall S22, respectively, and are substantially aligned with the sidewall S11 and the sidewall S22. In other words, in some embodiments, the projected areas of the two opposite end portions of the second heavily doped portion 109 on the substrate 100 connect to the projected areas of the first gate structure 110-1 and the second gate structure 110-2 on the substrate 100, respectively, and these projected areas substantially do not overlap.

According to some embodiments, as shown in FIG. 2, the second heavily doped portion 109 has a second length L2 in the first direction D1, and the second gate structure 110-2 is separated from the first gate structure 110-1 by a distance d1 in the first direction D1. In this example, the second length L2 is substantially equal to the distance d1 between the second gate structure 110-2 and the first gate structure 110-1.

Referring to FIGS. 1E-1 and 1E-2, according to some embodiments, after forming a planar gate structure 110 (e.g., the first gate structure 110-1 and the second gate structure 110-2) on the top surface 102a of the epitaxial layer 102, an interlayer dielectric (ILD) layer 113 is formed on the epitaxial layer 102, and multiple contacts 116 are formed in the interlayer dielectric layer 113.

Refer to FIGS. 1E-1 and 1E-2 and FIG. 3 simultaneously. FIG. 3 shows the top view of a semiconductor device at an intermediate manufacturing stage, according to some embodiments of the present disclosure. FIG. 1E-1 is a schematic cross-section view of a semiconductor device taken along, for example, the section line C1-C1 of FIG. 3, wherein the section line C1-C1 corresponds to the first heavily doped portion 108. FIG. 1E-2 is a schematic cross-section view of a semiconductor device taken along, for example, the section line C2-C2 of FIG. 3, wherein the section line C2-C2 corresponds to the lightly doped portion 107 and the second heavily doped portion 109. It should be noted that, for a clear top view of the semiconductor device, FIG. 3 only shows the contacts 116-S on the first heavily doped portions 108 and the second heavily doped portions 109, while omitting other contacts on the gate structure 110 and the trench structure 103.

According to some embodiments, as shown in FIGS. 1E-1 and 1E-2, the interlayer dielectric layer 113 is formed on the top surface 102a of the epitaxial layer 102 and covers the gate structures 110 (including the first gate structure 110-1 and the second gate structure 110-2), the first heavily doped portion 108, the second heavily doped portion 109, and the trench structures 103 (including the first trench structure 103-1 and the second trench structure 103-2).

In some embodiments, the interlayer dielectric layer 113 may be silicon oxide, other suitable low dielectric constant (low-k) dielectric material, or a combination thereof. In some embodiments, the material of the interlayer dielectric layer 113 is different from the material of the insulating layer 104 of the trench structure 103. In some other embodiments, the material of the interlayer dielectric layer 113 is the same as the material of the insulating layer 104 of the trench structure 103. Further, the interlayer dielectric layer 113 may be deposited above the epitaxial layer 102 by a deposition process. In some embodiments, the deposition process mentioned above may be a physical vapor deposition (PVD) process, a chemical vapor deposition (CVD) process, other suitable processes, or a combination thereof.

Subsequently, according to some embodiments, a portion of the interlayer dielectric layer 113 is removed to form a plurality of contact holes (not shown). More specifically, after the removal step, the contact holes formed expose the first gate structure 110-1, the second gate structure 110-2, the first trench structure 103-1, the second trench structure 103-2, a portion of the first heavily doped portion 108, and a portion of the second heavily doped portion 109.

Subsequently, according to some embodiments, a lithography patterning process and an etching process may be conducted to form contact holes in the interlayer dielectric layer 113. In one example, after depositing an interlayer dielectric material (not shown) on top of the epitaxial layer 102, the contact holes are formed by removing portions of the interlayer dielectric layer 113, for example, by one or more etching processes. In some embodiments, the lithography patterning process mentioned above comprises photoresist coating (e.g., spin coating), soft baking, mask alignment, exposure, post-exposure baking, photoresist development, cleaning and drying (e.g., hard baking), other suitable processes, or a combination thereof. In some embodiments, the etching process mentioned above may be a dry etching process, a wet etching process, a plasma etching process, a reactive ion etching process, other suitable processes, or a combination thereof.

In some examples, when viewed from above the epitaxial layer 102, the contact holes above the first heavily doped portion 108 and the second heavily doped portion 109 may be arranged substantially along the second direction D2, such as the position corresponding to the contacts 116-S as shown in FIG. 3. However, the present disclosure is not limited thereto. The contact holes may be arranged in one or more straight lines, or adjacent contact holes may be staggered.

Then, according to some embodiments, contacts 116 are formed in these contact holes. For example, as shown in FIGS. 1E-1 and 1E-2, contacts 116-S electrically connected to the first heavily doped portions 108 and the second heavily doped portions 109 (also referred to as source contacts), contact 116-T1 electrically connected to the first trench structure 103-1 and contact 116-T2 electrically connected to the second trench structure 103-2 (also referred to as trench contacts), and contact 116-G1 electrically connected to the first gate structure 110-1 and contact 116-G2 electrically connected to the second gate structure 110-2 (also referred to as gate contacts) are formed.

In some embodiments, each of the above-mentioned contacts includes a contact barrier layer 117 and a contact conductive layer 118. The contact barrier layer 117 is formed on the sidewall and the bottom surface of the contact hole as a barrier liner, and the contact conductive layer 118 fills the remaining space in the contact hole. In this example, as shown in FIGS. 1E-1 and 1E-2, the top surface of the contact (including the top surface of the contact barrier layer 117 and the top surface of the contact conductive layer 118) is substantially coplanar with the top surface of the interlayer dielectric layer 113.

In some examples, a barrier material (not shown) can be formed on the interlayer dielectric layer 113 through a deposition process, and the barrier material is isotropically deposited in the contact hole. Then a conductive material (not shown) is deposited above the barrier material layer, and the conductive material fills the remaining space in the contact hole. Next, excess portions of the conductive material and barrier material above the interlayer dielectric layer 113 are removed, for example, by etching or other suitable methods, to form the contact barrier layer 117 and the contact conductive layer 118 in the contact hole.

In some embodiments, the material of the contact barrier layer 117 may include titanium (Ti), titanium nitride (TiN), tantalum (Ta), tantalum nitride (TaN), cobalt (Co), cobalt tungsten phosphide (CoWP), ruthenium (Ru), aluminum trioxide (Al₂O₃), magnesium oxide (MgO), aluminum nitride (AlN), tantalum pentoxide (Ta₂O₅), silicon dioxide (SiO₂), hafnium dioxide (HfO₂), zirconium dioxide (ZrO₂), magnesium fluoride (MgF₂), calcium fluoride (CaF₂), other suitable barrier materials, or a combination thereof. In some embodiments, the contact barrier layer 117 may be formed by a chemical vapor deposition (CVD) process, an atomic layer deposition (ALD) process, a physical vapor deposition (PVD) process, other suitable processes, or a combination thereof.

In some embodiments, the contact conductive layer 118 may be a one- or multi-layer structure, and its conductive material may includes tungsten (W), aluminum (Al), copper (Cu), titanium (Ti), tantalum (Ta), titanium nitride (TiN), tantalum nitride (TaN), nickel silicide (NiSi), cobalt silicide (CoSi), tantalum carbide (TaC), tantalum silicon nitride (TaSiN), tantalum carbonitride (TaCN), titanium aluminide (TiAl), titanium aluminium nitride (TiAlN), other suitable metals, or a combination thereof. Furthermore, in some embodiments, the conductive material may be formed by a chemical vapor deposition process, an atomic layer deposition process, a physical vapor deposition process, other suitable processes, or a combination thereof.

Furthermore, in some other embodiments in which the conductive portion 105 of the trench structure 103 including in the epitaxial layer 102 and the gate electrode 112 of the gate structure 110 are polycrystalline silicon, before forming the contact hole, a self-aligned silicide (also known as Salicide) process may be conducted to form a metal silicide layer (not shown) layer on the first heavily doped portion 108, the second heavily doped portion 109, the conductive portion 105 and the gate electrode 112, respectively. After forming the contact hole, the conductive layer is filled in the contact hole to contact the underlying metal silicide layer. The metal silicide layer can reduce the contact resistance.

For example, a metal material may be formed on the first heavily doped portion 108, the second heavily doped portion 109, the conductive portion 105 and the gate electrode 112 by a chemical vapor deposition (CVD) process, an atomic layer deposition (ALD) process, a physical vapor deposition (PVD) process, other suitable processes, or a combination thereof. Then, a first annealing process is conducted, for example, using a rapid heating process (RTP), and the annealing temperature is, for example, in the range of 450° C. to 650° C. In some examples, the metal material includes titanium, cobalt, nickel, or other suitable materials. In the first annealing process with a lower temperature, the metal material reacts with silicon of the first heavily doped portion 108, the second heavily doped portion 109, the conductive portion 105 and the gate electrode 112 to form a high-resistance metal silicide first. After that, a second annealing process with a higher temperature is conducted, the annealing temperature is, for example, higher than 750° C., so that the high-resistance metal silicide is converted into a low-resistance metal silicide to form a metal silicide layer. Taking a metal material including titanium as an example, after the first annealing process, high-resistance Ti₂Si is formed first, and the second annealing process converts the high-resistance Ti₂Si into low-resistance TiSi₂. After forming the contact hole, a conductive layer is filled into the contact hole to contact the underlying metal silicide layer. In this example, since a continuous metal silicide layer is formed on the entire top surface of the first heavily doped portion 108 and the second heavily doped portion 109, the contact holes of the first heavily doped portion 108 and the second heavily doped portion 109 may be placed at any position, for example, the contact holes may be placed corresponding to the first doped portion 108, corresponding to the second doped portion 109, or corresponding to the position between the first doped portion 108 and the second doped portion 109, and the subsequently formed contact 116S can be well electrically connected to the first heavily doped portion 108 and the second heavily doped portion 109.

After forming the contacts, such as the contacts 116-S, 116-T1, 116-T2, 116-G1 and 116-G2 shown in FIGS. 1E-1 and 1E-2, other subsequent process of other features may be conducted. According to some embodiments, a metal layer (not shown) is formed over the interlayer dielectric layer 113 and the contacts. The metal layer covers the contacts and is in physical and electrical contact with the contacts. Therefore, the metal layer is electrically connected to the first heavily doped portion 108, the second heavily doped portion 109 and the well region 106 through the contacts.

In some embodiments, the metal layer may include copper, silver, gold, aluminum, tungsten, other suitable metal materials, or a combination thereof. In some embodiments, the metal layer is made of the same material as the contacts. In some other embodiments, the metal layer is made of a different material from the contacts. According to some embodiments, the metal layer may be formed on the contacts through a deposition process. In some embodiments, the deposition process mentioned above may be a physical vapor deposition process, a chemical vapor deposition process, other suitable processes, or a combination thereof. After the metal layer is formed, the process of a semiconductor device 10 is completed. According to some embodiments, the metal layer may be used as the top metal of a semiconductor device 10 to be electrically connected to the first heavily doped portion 108 serving as the source region, and therefore may also be referred to as a source metal layer.

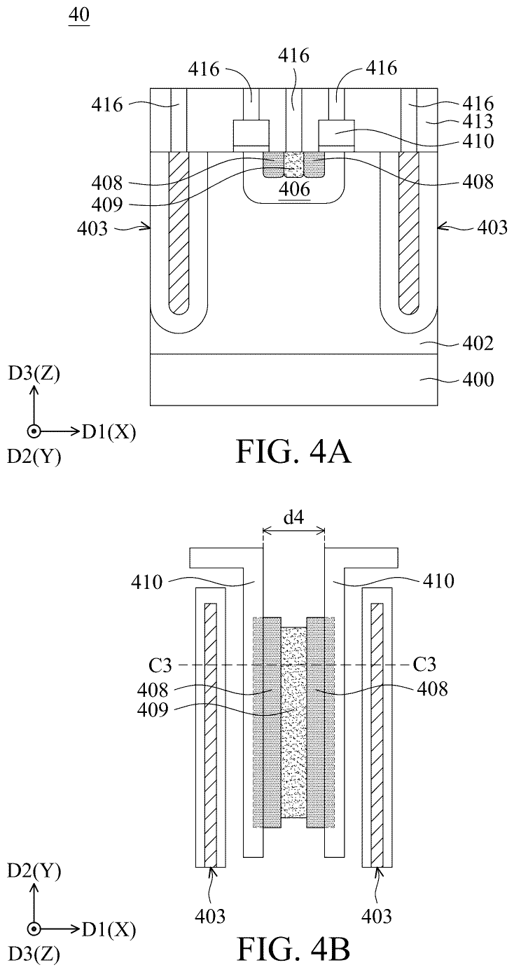

In addition, FIGS. 4A and 4B show the schematic cross-sectional view and the top view, respectively, of a semiconductor device at an intermediate manufacturing stage. It should be noted that, for a clear top view of the semiconductor device, FIG. 4B omits the interlayer dielectric layer on the epitaxial layer, and omits multiple contacts on the gate structure, trench structure 103 and the heavily doped portion serving as the source/base. Further, the features in FIGS. 4A and 4B that are the same or similar to FIGS. 1E-1 and 1E-2 use the same or similar reference numerals, and reference may be made to the contents of these features in the embodiments above.

The semiconductor device 40 shown in FIGS. 4A and 4B includes an epitaxial layer 402 on a substrate 400, a trench structure 403 in the epitaxial layer 402, a first heavily doped portion 408 and a second heavily doped portion 409 in a well region 406, a gate structure 410 and an interlayer dielectric layer 413 on the epitaxial layer 402, and contacts 416 connecting to the trench structure 403, the first heavily doped portions 408, the second heavily doped portion 409 and the gate structure 410, respectively. The first heavily doped portions 408 and the second heavily doped portion 409 are source regions and bulk region of the semiconductor device 40, respectively.

Details of the configuration, materials, and forming methods of each feature in the semiconductor device 40, such as relative positions, conductivity types, and implantation of dopants, may refer to the descriptions related to FIGS. 1A to 1E-1, 1E-2 and 2 mentioned above, and will not be repeated herein.

According to the semiconductor device 40 shown in FIG. 4B, the trench structure 403, the first heavily doped portion 408, the second heavily doped portion 409 and the gate structure 410, for example, all extend in the second direction D2. In other words, the extending direction (e.g., the second direction D2) of the first heavily doped portion 408 and the second heavily doped portion 409 is substantially parallel to the extending direction of the gate structure 410. Furthermore, as shown in FIG. 4B, one strip-shaped second heavily doped portion 409 (as the bulk region) is generally disposed between two strip-shaped first heavily doped portions 408 (as the source region). This means that three strip-shaped heavily doped portions 408 and 409 need to be disposed in the space where two adjacent gate structures 410 are separated by a distance d4 in the first direction D1.

However, the width of each heavily doped portion of the first heavily doped portion 408 and the second heavily doped portion 409 in the first direction D1 is related to the capability of the lithography etching process. In other words, the widths of the first heavily doped portion 408 and the second heavily doped portion 409 are also limited by the capability of the photolithography etching process, which in turn prevents further reduction of distance between the two neighboring gate structures 410 after a certain distance d4 has been reached. The embodiment disclosed herein mainly proposes that the first heavily doped portion 108 and the second heavily doped portion 109 be disposed alternately in the second direction D2, so that the distance d1 between two neighboring gate structures 110 in the first direction D1 can be shortened, thus reducing the cell pitch for semiconductor devices on wafers and improving the yields of the semiconductor devices produced.

Accordingly, compared with the semiconductor device 40 of FIG. 4B and the semiconductor device 10 of FIG. 2, the distance d1 between the two neighboring gate structures 110 in the first direction D1 in FIG. 2 is significantly smaller than the distance d4 between the two neighboring gate structures 410 in the first direction D1 in FIG. 4B. For example, the distance d4 that would otherwise be required to place the three strip-shaped heavily doped portions 408 and 409 may, in some embodiments, only be required to be the distance of one strip-shaped heavily doped portion. That is, the distance d1 is smaller than the distance d4, or the distance d1 is less than or equal to ⅓ of the distance d4.

In addition, the present disclosure is not limited to the feature configurations of the semiconductor devices mentioned above. According to some other embodiments, another trench structure may further be included in the epitaxial layer, and this trench structure passes through the well region 106.

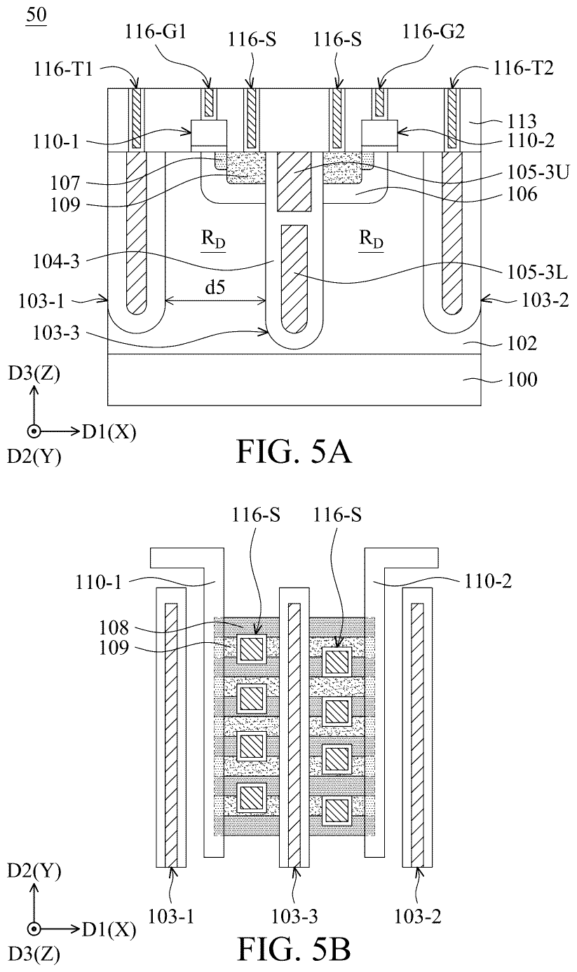

FIGS. 5A and 5B show the schematic cross-sectional view and the top view, respectively, of a semiconductor device at an intermediate manufacturing stage, according to some embodiments of the present disclosure. It should be noted that, for clarity of the top view of the semiconductor 50, FIG. 5B omits the interlayer dielectric layer on the epitaxial layer and omits multiple contacts on the gate structure and trench structure.

Further, the features in FIGS. 5A, 5B that are the same or similar to those in FIGS. 1E-1 and 1E-2 use the same or similar reference numerals. Details of the configuration, material, and fabrication of the various features in the semiconductor device 50, such as the relative positions, the conductive types, and the implantation of dopants, may refer to the relevant descriptions of these features in FIGS. 1A-1E-1, 1E-2, and 2 above, which will not be repeated here.

According to some embodiments, the semiconductor device 50 shown in FIGS. 5A and 5B includes an epitaxial layer 102 on a substrate 100, trench structures 103 (including a first trench structure 103-1, a second trench structure 103-2 and a third trench structure 103-3) in the epitaxial layer 102, a lightly doped portion 107, a first heavily doped portion 108 and a second heavily doped portion 109 alternately disposed along the second direction D2 in a well region 106, gate structures 110 (including a first gate structure 110-1 and a second gate structure 110-2) on the epitaxial layer 102, and an interlayer dielectric layer 113.

The semiconductor device 50 further includes contacts 116-T1, 116-T2, 116-S, 116-G1, and 116-G2 in the interlayer dielectric layer 113, connecting the first trench structure 103-1, the second trench structure 103-2, the first heavily doped portion 108, the second heavily doped portion 109, the first gate structure 110-1, and the second gate structure 110-2, respectively. The first heavily doped portion 108 and the second heavily doped portion 109 are the source region and the bulk region of the semiconductor device 50, respectively.

According to some embodiments, similar to the arrangement of the first trench structure 103-1 and the second trench structure 103-2, the third trench structure 103-3 extends in the third direction D3 from the top surface 102a of the epitaxial layer 102 and passes through the well region 106. In this example, the third trench structure 103-3 also extends along the second direction D2, which is the same as the extending direction of the first trench structure 103-1 and the second trench structure 103-2. Furthermore, the third trench structure 103-3 is separated from the first trench structure 103-1 and the second trench structure 103-2 by a distance d5 respectively in the first direction D1.

Furthermore, in some embodiments, the third trench structure 103-3 may have a similar profile and include the same material as the first trench structure 103-1 and the second trench structure 103-2. However, in some other embodiments, as shown in FIGS. 5A and 5B, the third trench structure 103-3 may also be a split-gate trench structure. The disclosure is not limited thereto.

In some embodiments, as shown in FIG. 5B, the third trench structure 103-3 includes an insulating liner 104-3 and a conductive filling layer 105-3. The conductive filling layer 105-3 includes a conductive lower portion 105-3L and a conductive upper portion 105-3U, which are isolated from each other by a portion of the insulating liner 104-3. Furthermore, in some embodiments, the insulating layer 104 of the first trench structure 103-1 and the second trench structure 103-2 includes the same material as the insulating liner layer 104-3 of the third trench structure 103-3, and the conductive portion 105 of the trench structure 103-1 and the second trench structure include the same material as the conductive lower portion 105-3L and the conductive upper portion 105-3U of the third trench structure 103-3.

In some embodiments, as shown in FIG. 5B, if viewed from above the substrate 100, the extending direction of the first heavily doped portion 108 and the second heavily doped portion 109 (for example, the first direction D1) are perpendicular to the extension direction of the second trench structure (for example, the second direction D2), respectively.

Furthermore, according to some embodiments, as shown in FIG. 5B, in addition to the first heavily doped portion 108 and the second heavily doped portion 109 alternately being disposed along the second direction D2 (for example, along the extending direction of the channel width of the semiconductor device), the first heavily doped portion 108 and the second heavily doped portion 109 extend along the first direction D1 and pass through the third trench structure 103-3.

In summary, according to the semiconductor device and the method of forming the same in some embodiments of the present disclosure, the first heavily doped portion and the second heavily doped portion on one side of the planar gate structure and disposed alternately along the extending direction of the gate structure (i.e., the second direction D2 in the figures) can be formed, wherein the first heavily doped portion and the second heavily doped portion are of different conductive types. In some embodiments in which the semiconductor device is a VDMOS device, the first heavily doped portion and the second heavily doped portion may serve as the source region and the bulk region of the VDMOS device respectively. As mentioned above, the semiconductor device, in which the first heavily doped portion and the second heavily doped portion are alternately disposed as proposed in the embodiment, can overcome the width limitation of the first heavily doped portion and the second heavily doped portion imposed by the capability of the lithography etching process, and reduce the distance between the two neighboring gate structures 110 in the direction (i.e., the first direction D1 in the figures) different from the extending direction of the gate structures. Accordingly, by applying the semiconductor device and the method for forming the same in some embodiments of the present disclosure, the cell pitch for fabricating semiconductor devices on a wafer can be reduced, thereby increases the total number of semiconductor devices on the wafer and the yield of the semiconductor devices produced.

Furthermore, by the method for forming the semiconductor device proposed in the embodiment of the present disclosure, the first heavily doped portions and the second heavily doped portions alternately disposed can be formed through processes that are compatible with the existing processes. Thus, the method also has the advantages such as simple manufacturing process and can be conducted by existing processing machine without increasing additional manufacturing costs significantly. Furthermore, the embodiments of the present disclosure are suitable for manufacturing scaled-down or miniaturized semiconductor devices to increase the density of semiconductor devices on a wafer to increase the total number of semiconductor devices on the wafer. Therefore, the embodiments of the present disclosure can reduce the production cost and energy consumption of manufacturing a single semiconductor device, thereby reducing carbon emissions during the production of each unit of the semiconductor device. In addition, since the semiconductor device and its forming method of the present disclosure can improve device yield and reduce waste of materials and energy during the manufacturing process, the embodiments of the present invention also provide green semiconductor technology.

Although the present embodiments and their advantages have been described in detail, it should be understood that various changes, substitutions, and alterations can be made herein without departing from the spirit and scope of the disclosure. Moreover, the scope of the present disclosure is not intended to be limited to the particular embodiments of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps. In addition, each claim constitutes a separate embodiment, and the combination of various claims and embodiments are within the scope of the disclosure.

What is claimed is:

1. A semiconductor device, comprising:
a substrate having a first conductivity type;
an epitaxial layer formed on the substrate and having the first conductivity type;
a trench structure extending from a top surface of the epitaxial layer into the epitaxial layer, and including a conductive portion and an insulating layer that covers a sidewall and a bottom surface of the conductive portion;
a well region extending from the top surface of the epitaxial layer into the epitaxial layer and having a second conductivity type, wherein the well region is separated from the trench structure in a first direction, and the well region extends in a second direction different from the first direction;
at least one first heavily doped portion and at least one second heavily doped portion formed in the well region and extending in the first direction, and alternately disposed in the second direction, wherein the first heavily doped portion has the first conductivity type and the second heavily doped portion has the second conductivity type; and
a gate structure formed on the top surface of the epitaxial layer and corresponding to the well region, wherein the gate structure extends in the second direction.

2. The semiconductor device as claimed in claim 1, wherein the first heavily doped portion is a source region and the second heavily doped portion is a bulk region.

3. The semiconductor device as claimed in claim 1, wherein the first heavily doped portion connects to the second heavily doped portion in the second direction, and a first sidewall of the first heavily doped portion abuts a second sidewall of the second heavily doped portion.

4. The semiconductor device as claimed in claim 3, further comprising:
a lightly doped portion extending in the second direction and having the first conductivity type,
wherein the first sidewall of the first heavily doped portion and the second sidewall of the second heavily doped portion are perpendicular to the extending direction of the lightly doped portion.

5. The semiconductor device as claimed in claim 1, wherein a channel width of the semiconductor extends in the second direction.

6. The semiconductor device as claimed in claim 1, comprising a plurality of the first heavily doped portions and a plurality of the second heavily doped portions alternately disposed in the second direction.

7. The semiconductor device as claimed in claim 6, further comprising:
a lightly doped portion extending in the second direction and having the first conductivity type,
wherein the lightly doped portion connects to the plurality of the first heavily doped portions and the plurality of the second heavily doped portions that are alternately disposed.

8. The semiconductor device as claimed in claim 7, wherein one of the plurality of the second heavily doped portions is surrounded by two of the plurality of the first heavily doped portions and the lightly doped portion.

9. The semiconductor device as claimed in claim 1, wherein the first heavily doped portion has a first length in the first direction, the second heavily doped portion has a second length in the first direction, and the first length is longer than the second length.

10. The semiconductor device as claimed in claim 1, wherein the gate structure is a first gate structure corresponding to one side of the well region, wherein the semiconductor device further comprises:
a second gate structure formed on the top surface of the epitaxial layer and corresponding to another side of the well region,
wherein the second gate structure extends along the second direction, and the second gate structure is separated from the first gate structure by a first distance in the first direction.

11. The semiconductor device as claimed in claim 10, wherein two opposite end portions of the first heavily doped portion respectively extend to below two adjacent sidewalls of the first gate structure and the second gate structure, and partially overlap the first gate structure and the second gate structure.

12. The semiconductor device as claimed in claim 10, wherein two opposite end portions of the second heavily doped portion respectively extend to below two adjacent sidewalls of the first gate structure and the second gate structure, respectively.

13. The semiconductor device as claimed in claim 10, wherein the first heavily doped portion has a first length in the first direction, and the first length is longer than the first distance between the second gate structure and the first gate structure.

14. The semiconductor device as claimed in claim 10, wherein the second heavily doped portion has a second length in the first direction, and the second length is equal to the first distance between the second gate structure and the first gate structure.

15. The semiconductor device as claimed in claim 10, wherein the trench structure is a first trench structure, and the semiconductor further comprises:
a second trench structure extending in a third direction from the top surface of the epitaxial layer and through the well region, wherein the second trench structure and the first trench structure extend in the second direction and are separated from each other by a second distance in the first direction.

16. The semiconductor device as claimed in claim 15, wherein viewed from above the substrate, extending directions of the first heavily doped portion and the second heavily doped portion are respectively perpendicular to an extending direction of the second gate structure.

17. The semiconductor device as claimed in claim 15, wherein the first heavily doped portion and the second heavily doped portion extend in the first direction and pass through the second trench structure.

18. The semiconductor device as claimed in claim 15, wherein the second trench structure comprises a conductive filler layer and an insulating liner covering a sidewall and a bottom surface of the conductive filler layer.
